(19) United States
(12) Patent Application Publication
(10) Pub. No.: US 2011/0272733 A1
(43) Pub. Date: Nov. 10, 2011

(54) ENCAPSULATION STRUCTURE FOR LIGHT-EMITTING DIODE

(76) Inventor: Hsin-Lung CHEN, Yonghe City (TW)

(21) Appl. No.: 12/776,037

(22) Filed: May 7, 2010

(51) Int. Cl. H01L 33/56

(52) U.S. Cl. 257/100; 257/E33.059

(57) ABSTRACT

The present invention relates to an encapsulation structure for light-emitting diode, primarily assembled from an encapsulation base, light-emitting diode chips and transparent encapsulation material, in which the light-emitting diode chips are mounted on an encapsulation region of the encapsulation base, after which the transparent encapsulation material is used to overlay the predetermined positions of the light-emitting diode chips. Accordingly, the light rays produced by the light-emitting diode chips can be emitted from the side areas, and when the light-emitting diode chips are mounted and joined to the encapsulation bases, then brightness at the connected areas can be maintained, and uneven brightness is prevented from occurring.

### BACKGROUND OF THE INVENTION

(a) Field of the Invention

The present invention provides a light-emitting diode, and more particularly provides an encapsulation structure for light-emitting diode able to maintain and achieve equal brightness at connected areas of a plurality of light-emitting diodes.

(b) Description of the Prior Art

Referring to FIG. 1, which shows a light-emitting diode encapsulation structure of the prior art, in which at least one light-emitting diode chip 20 is mounted on an encapsulation base 2, and opaque encapsulation material 22 (such as: epoxy resin or acrylic) is used to encircle the periphery of the light-emitting diode chip 20. Accordingly, when the light-emitting diode chip 20 is mounted with and joined to the encapsulation base 2, because the opaque encapsulation material 22 impedes side light from the light-emitting diode chip 20, thus, light at the area where the light-emitting diode chip 20 and the encapsulation base 2 join is evidently darker compare to the non-joining area. Hence, when using such a light-emitting diode encapsulation structure in an extensive illuminating area, then the naked eye can detect the uneven brightness of light and dark areas.

Thus, it is the strong desire of the inventor and manufacturers engaged in related art and purpose of the present invention to research, improve and resolve the problems and shortcomings of the aforementioned prior art.

### SUMMARY OF THE INVENTION

Hence, in light of the shortcomings of the aforementioned prior art, the inventor of the present invention, having collected related data, and through evaluation and consideration from many aspects, as well as having accumulated years of experience in related arts, through continuous testing and improvements, has designed a new encapsulation structure for light-emitting diode able to maintain, and achieve equal brightness at connected areas of a plurality of light-emitting diodes.

The primary objective of the present invention lies in an encapsulation structure for light-emitting diode, primarily assembled from an encapsulation base, light-emitting diode chips and transparent encapsulation material, in which the light-emitting diode chips are mounted on an encapsulation region of the encapsulation base, after which the transparent encapsulation material is used to overlay the predetermined positions of the light-emitting diode chips. The transparent encapsulation material (such as: silicone) is doped with a predetermined measure of phosphor (fluorescent powder). Accordingly, the light rays produced by the light-emitting diode chips can be emitted from the side areas, and when the light-emitting diode chips are mounted and joined to the encapsulation bases, then brightness at the connected areas can be maintained, and uneven brightness will be prevented from occurring.

Another objective of the present invention lies in doping the transparent encapsulation material with phosphor (fluorescent powder) of different composition to achieve different color temperature and conform with customization conditions.

To enable a further understanding of said objectives and the technological methods of the invention herein, a brief description of the drawings is provided below followed by a detailed description of the preferred embodiments.

### BRIEF DESCRIPTION OF THE DRAWINGS

FIG. 1 shows a light-emitting diode encapsulation structure of the prior art.

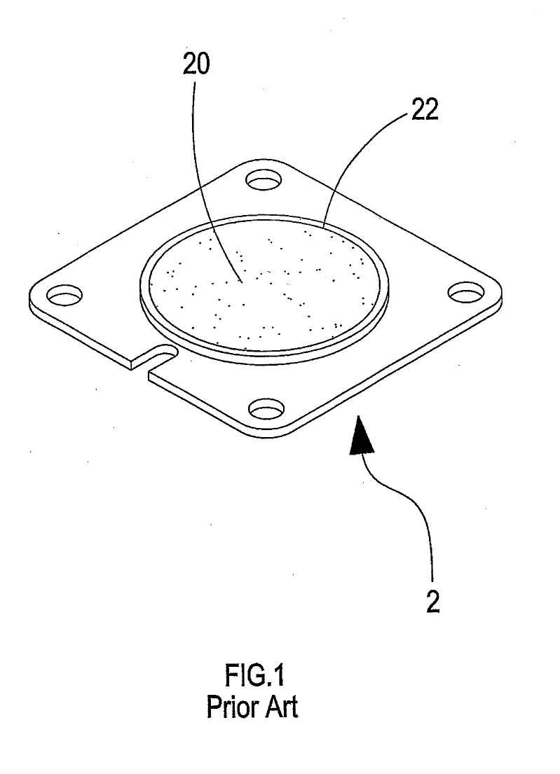

FIG. 2 is an elevational schematic view of a preferred embodiment of the present invention.

FIG. 3 is a schematic cross-sectional view of the preferred embodiment of the present invention.

FIG. 4 is a schematic view depicting a cross section of an operating state of the preferred embodiment according to the present invention.

### DETAILED DESCRIPTION OF THE PREFERRED EMBODIMENTS

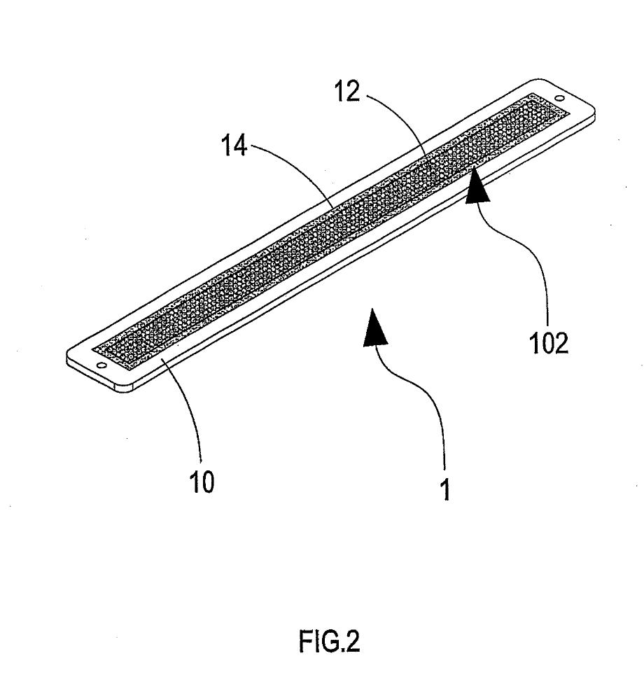

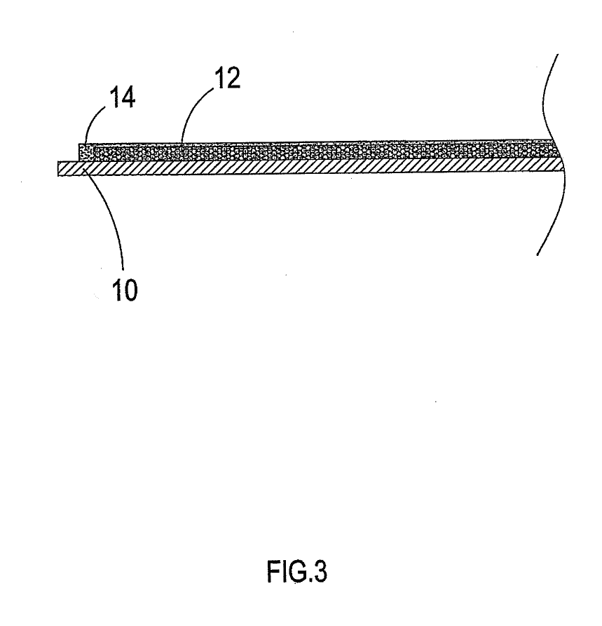

Referring to FIG. 2 and FIG. 3, which show an elevational schematic view and a schematic cross-sectional view respectively of a preferred embodiment of the present invention, and it can be clearly seen from the drawings that the present invention comprises an encapsulation structure for light-emitting diode, in which an encapsulation structure 1 is primarily assembled from an encapsulation base 10, light-emitting diode chips 12 and transparent encapsulation material 14. An encapsulation region 102 is defined on the encapsulation base 10, and at least one of the light-emitting diode chips 12 is mounted on the encapsulation region 102, after which the transparent encapsulation material 14 is used to overlay the predetermined positions of the light-emitting diode chips 12. Because the encapsulation material 14 is a transparent material (such as: silicone), thus, the light-emitting diode chips 12 are able to produce side light, thereby expanding the illumination range. In addition, the transparent encapsulation material 14 is doped with a predetermined measure of phosphor (fluorescent powder), and phosphor (fluorescent powder) of different composition enables achieving different color temperature.

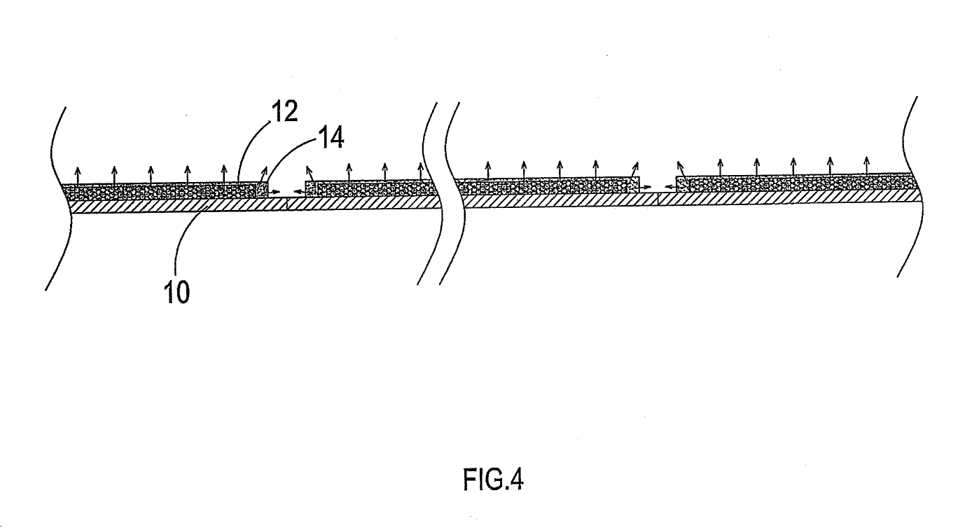

According to the aforementioned structure and constructional design, circumstances during operational use of the present invention are described hereinafter. Referring together with FIG. 4, which shows a schematic view depicting a cross section view of an operating state of the preferred embodiment according to the present invention, and it can be clearly seen from the drawing that when using the encapsulation base 10 mounted with the light-emitting diode chips 12 to increase illumination range, then the illumination range can be freely changed by merely using a series or parallel mounting means. Because the transparent encapsulation material 14 overlaying the light-emitting diode chips 12 enables side light from the light-emitting diode chips 12 to be transmitted therethrough, thus, regardless of how extensive the illuminating area being used, illumination effectiveness thereof is extremely uniform, and uneven brightness of light and dark regions will not occur.

In conclusion, the encapsulation structure for light-emitting diode of the present invention is clearly able to achieve the effectiveness and objectives as disclosed when in use, and is indeed a practical and exceptional invention that complies with the essential elements as required for a new patent application. Accordingly, a new patent application is proposed herein.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. An encapsulation structure for light-emitting diode, comprising:
an encapsulation base, an encapsulation region is defined on the encapsulation base;
at least one light-emitting diode chip, the light-emitting diode chips are mounted on the encapsulation the region; and
a transparent encapsulation material, the transparent encapsulation material overlays the predetermined positions of the light-emitting diode chips.

2. The encapsulation structure for light-emitting diode according to claim 1, wherein the transparent encapsulation material is doped with a predetermined measure of phosphor (fluorescent powder).

3. The encapsulation structure for light-emitting diode according to claim 1, wherein the transparent encapsulation material is silicone.

4. The encapsulation structure for light-emitting diode according to claim 2, wherein the transparent encapsulation material is silicone.
